(19) United States
(12) Patent Application Publication
(10) Pub. No.: US 2011/0248919 A1
(43) Pub. Date: Oct. 13, 2011

(54) Method to enter characters into an electronic system

(76) Inventor: Sergei Bashinsky, Moscow (RU)

(21) Appl. No.: 12/662,271

(22) Filed: Apr. 8, 2010

(51) Int. Cl. G06F 3/02; H03M 11/02

(52) U.S. Cl. 345/168; 341/22

(57) ABSTRACT

The present invention relates to a method of entering keyboard characters in an electronic system. The method includes detecting movement of at least one of a first input agent and a second input agent, calculating at least one of a first end direction that characterizes direction of a last portion of movement of the first input agent and a second end direction that characterizes direction of a last portion of movement of the second input agent, and determining end of movement of the first and second input agents. The method further includes determining the keyboard character from a plurality of keyboard characters based on at least one of the calculated first end direction and the calculated second end direction.

### BACKGROUND

The most common form of entering letters, numbers and/or symbols into an electronic system, such as a computer, involves the operator typing the characters on a keyboard. Although keyboard layouts have changed over the years, most U.S. keyboard layouts employ a variation of a US 102-key PC/AT keyboard.

As computer keyboards have become widespread, so have become health problems caused by repeated keyboard typing. For example, the United States Department of Labor, Occupational Safety and Health Administration has reported Repetitive Strain Injuries (RSI), for which computer work has become the prevailing cause, to be the most widespread and costly occupational health problem, affecting hundreds of thousands of Americans. Worldwide RSI affect millions of people. According to U.S. Bureau of Labor Statistics, approximately two-thirds of all occupational illnesses reported in the United States were caused by exposure to repeated trauma to workers upper body. Surgery for Carpal Tunnel Syndrome, one of the better publicized although not even the most common computer-inflicted motor impairment, is presently the second most performed type of surgery in the United States.

Besides the dramatic reduction of quality of life, an unfortunate repercussion of a keyboard-related injury is prolonged or permanent limitation for an injured person to perform any occupational and social activity involving keyboards. With the ubiquitous role that computers have taken in the modern life, alternative means of entering text into a computer or an electronic system for such people become highly desirable. The recent decades have seen numerous attempts to design efficient solutions, developing along two general directions: keyboards with improved ergonomics, and keyboard replacements. The designed ergonomic keyboards, e.g. Microsoft's Natural Ergonomic Keyboard or Kinesis' Contoured Keyboard, allow for a more natural wrist alignment and placement of hands that minimizes awkward postures. By this, ergonomic keyboards can partly alleviate some of the symptoms and slow further health damage. Yet they neither eliminate typing nor change general mechanics of it—pressing individual keys by moving operator's fingers.

Of the true keyboard replacements, speech recognition software has proven to be a particularly promising accessibility solution. The best contemporary speech recognition programs can now recover much of the text dictated. Nonetheless, frequent errors continue to occur due to numerous homophones (words with different spelling but similar or same pronunciation), variations of pronunciation, and diversity of accents. As a result, this often requires continuous corrections, most efficiently entered by manual typing. Speech recognition may further be disrupted by external noise, such as traffic noise and voices, common for urban and office environments. Another practical inconvenience of using speech recognition in the office is the need to pronounce audibly, for people around to hear, all the text to be typed. For most languages other than English, speech recognition software is in substantially inferior development stage or non-existent. Thus even this partial solution is inaccessible to the majority of the world population. For the reasons listed above, a fast and robust alternative method of key entering remains desirable.

Methods have been developed to enter characters by movement of users' body parts other than fingers. Examples are movement of person's eyes, a hand as a whole, or an object—pen or stylus—grasped by a hand, for example. Many of them involve a dedicated mechanical device: a pupil movement reader, a special mechanical apparatus, or a tablet, for example. Such mechanical devices, while being limited in their efficiency, entail a baggage of inconveniences. On the production side, these mechanical devices require manufacturing non-standard equipment in relatively minor quantities, at either elevated cost or reduced quality, as compared to what it could be achieved by mass production. While on the consumer side, these mechanical devices need investment in often expensive equipment whereas it is generally difficult to predict how much this device would help under the specific injury to perform specific tasks and for how long it will be required. Bulky mechanical attachments, furthermore, entail sacrifice of at least some mobility, such as the ability to type anywhere at home, in the workplace, and on travel.

An ideal keyboard replacement should be readily available, inexpensive, portable, and simple in operation. Existing on-screen (or virtual) keyboards feature the above requirements. Yet conventional on-screen keyboards lack another desirable property—typing efficiency. While on-screen keyboards can offer reliable character recognition, entering characters into an electronic system is frustratingly slow. The conventional on-screen methods require a user to visually find a key image on the screen, move a mouse pointer onto it, and stop the pointer exactly within the area associated with the intended key. Afterwards, the user should also signal his intention to enter this key by either clicking the mouse or by letting the mouse pointer hover over the key image for additional of time. This technique involves sufficient muscle strain for moving the mouse precisely onto the desired key, and demands considerably more time than striking a mechanical keyboard key with a finger. Moreover, because the operator has to look at the on-screen keyboard, away from the text typed, “touch-typing” (typing without looking at the keyboard layout to find the keys) becomes practically impossible.

### SUMMARY

The present invention relates to a new method of entering keyboard characters in an electronic system. Embodiments of this method can retain the aforementioned advantages of on-screen keyboards. For example, after activating an easily downloadable software program, typing can be performed by any mass-produced inexpensive pointing devices, e.g. computer mice, available wherever computers are. In addition, the present embodiments can remove the major impediments of the existing on-screen keyboards, as well as enhance the speed of typing and support natural touch-typing.

The method includes detecting movement of at least one of a first input agent and a second input agent. The method further comprises calculating at least one of (1) a first end direction that characterizes a direction of a last portion of movement of the first input agent, and (2) a second end direction that characterizes a direction of a last portion of movement of the second input agent. The method also includes determining end of movement of the first and second input agents. The method's determination of the keyboard character is based on at least one of the calculated first end direction and the calculated second end direction.

The method may further include performing at least one of the two steps: (1) while movement is detected for the first input agent, detecting a plurality of first displacements for the first input agent, and (2) while movement is detected for the second input agent, detecting a plurality of second displacements for the second input agent. If step (1) has occurred, the first end direction may then be calculated based on the detected plurality of first displacements. Likewise, if step (2) has occurred, the second end direction may then be calculated based on the detected plurality of second displacements.

In one embodiment of the method, the first end direction is a direction of a displacement that was detected last for the first input agent, and the second end direction is a direction of a displacement that was detected last for the second input agent.

In another embodiment, the first end direction is the direction of a first sum vector. The first sum vector is calculated by adding a displacement of the first input agent that was detected last with previously detected displacements of the first input agent in reverse chronological order until a length of the resulting first sum vector exceeds a threshold value. Similarly, the second end direction is a direction of a second sum vector, calculated by adding a displacement of the second input agent that was detected last with previously detected displacements of the second input agent in reverse chronological order until a length of the resulting second sum vector exceeds a threshold value.

In some embodiments, each of the calculated first and second end directions is further reduced to one of an up direction, a down direction, a left direction, and a right direction.

In some embodiments, the step of determining end of movement of the first and second input agents comprises registering no movement of the first input agent and the second input agent continuously for a period of time, where the period of time is a non-negative parameter.

The method, in some embodiments, may further include assigning a state to each of the first input agent and the second input agent from a plurality of states, where the plurality of states includes a passive state and an active state. If the first input agent is assigned the active state and the second input agent is assigned the passive state when the end of movement is determined, then the keyboard character is determined based on at least the calculated first end direction. If the first input agent is assigned the passive state and the second input agent is assigned the active state when the end of movement is determined, then the keyboard character is determined based on at least the calculated second end direction. If the first input agent is assigned the active state and the second input agent is assigned the active state when the end of movement is determined, then the keyboard character is determined based on at least the calculated first end direction and the calculated second end direction.

Embodiments of the method may further include displaying at least some of the plurality of keyboard characters.

Displaying may comprise displaying a first group corresponding to the first input agent being active and the second input agent being passive, displaying a second group corresponding to the second input agent being active and the first input agent being passive, and a third group corresponding to both the first and second input agents being active.

Displaying may further include displaying a first cursor for the first input agent in the first group after a previous input choice is entered, where the starting position of the first cursor—at a first location—does not depend on the current physical position of the first input agent. Similarly, it may include displaying a second cursor for the second input agent in the second group after a previous input choice is entered, where the starting position of the second cursor—at a second location—does not depend on the current physical position of the second input agent.

Another embodiment further includes: displaying a first arrow in the first group instead of the first cursor when the first input agent is active and the second input agent is passive, where the first arrow indicates a current first end direction. Likewise, the embodiment includes displaying a second arrow in the second group instead of the second cursor when the second input agent is active and the first input agent is passive, where the second arrow indicates a current second end direction. The embodiment also includes displaying third and fourth arrows in the third group when the first and second input agents are active, where the third arrow indicates a current first end direction, and the fourth arrow indicates a current second end direction.

Another embodiment offers visual feedback by displaying the determined keyboard character in a typing field. The typing field can either be displayed by an embodiment of this method or be a text display field of an independent application to which the keyboard characters are entered. If the determined character changes before a completion of entering the current character, then the character is redisplayed.

Embodiments of the present invention also include entering keyboard characters in an electronic system. The method includes generating a first value and a second value, each value indicating one of a passive state, an up direction, a down direction, a left direction, and a right direction. The embodiment further includes determining the input choice based on at least the generated first value, the generated second value, and a main letter map. The main letter map includes letter input choices given by the following table:

| | 2^{nd} value | | | | |
|---|---|---|---|---|---|
| 1^{st} value | Passive | Up | Down | Left | Right |
| Passive | | t | | | n |
| Up | i | c | h | f | m |
| Down | e | d | | p | |
| Left | a | w | | l | s |
| Right | o | u | g | | r |

Another embodiment further includes switching among the main letter map and an extended letter map, where the switching is based on at least one of (1) the first value, (2) the second value, or (3) an input signal independent from the first and second values. The extended letter map includes letter input choices given by the following table:

| | 2^{nd} value | | | | |
|---|---|---|---|---|---|
| 1^{st} value | Passive | Up | Down | Left | Right |
| Passive | | v | | | |
| Up | y | | q | | |
| Down | x | j | | | |
| Left | b | | | | z |
| Right | k | | | | |

Another embodiment includes switching among the main letter map and a number map, where the switching is based on at least one of (1) the first value, (2) the second value, or (3) an input signal independent from the first and second values. The number map includes number input choices given by the following table:

| | 2^{nd} value | | | | |
|---|---|---|---|---|---|
| 1^{st} value | Passive | Up | Down | Left | Right |
| Passive | | 8 | | | 9 |
| Up | 2 | | 5 | | |
| Down | 0 | 6 | | | |
| Left | 1 | | | 4 | |
| Right | 3 | | | | 7 |

### BRIEF DESCRIPTION OF THE DRAWINGS

Example embodiments will become more fully understood from the detailed description presented herein below and the accompanying drawings. These example embodiments are given by way of illustration only and thus are not limiting the present invention.

FIG. 1 illustrates an application of the method of entering keyboard characters by an end user according to an embodiment of the present invention;

FIG. 2A illustrates a method of entering keyboard characters in an electronic system according to an embodiment of the present invention;

FIG. 2B illustrates a method of entering keyboard characters in an electronic system according to another embodiment of the present invention;

FIG. 3 illustrates a plurality of keyboard characters and two pointers displayed on a visual display at the start of typing or at the start of typing of a new character after determining end of movement of the first and second input agents according to embodiments of the present invention;

FIG. 4 illustrates a plurality of keyboard characters, a first arrow and a second pointer displayed on the visual display when the first input agent is in an active state and the second input agent is in a passive state according to embodiments of the present invention;

FIG. 5 illustrates a plurality of keyboard characters, and third and fourth arrows displayed on the visual display unit when both the first and second input agents are in active states according to embodiments of the present invention;

FIG. 6 illustrates switching between a main letter layout map and an extended letter layout map according to an embodiment of the present invention;

FIG. 7 illustrates the main letter layout map and the extended letter layout map according to an embodiment of the present invention;

FIG. 8 illustrates a number layout map according to an embodiment of the present invention;

FIG. 9 illustrates a symbol layout map according to an embodiment of the present invention;

FIG. 10 illustrates a directional symbol layout map according to an embodiment of the present invention; and

FIG. 11 illustrates a function layout map according to an embodiment of the present invention.

### DETAILED DESCRIPTION OF EXAMPLE EMBODIMENTS

Various embodiments of the present invention will now be described more fully with reference to the accompanying drawings. Like elements on the drawings are labeled by like reference numerals.

As used herein, the singular forms “a”, “an”, and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the described functions/acts may occur out of the order shown in the figures. For example, two steps that are shown in a figure in succession may, in fact, be executed substantially concurrently or may in other embodiments be even executed in the reverse order, depending upon the functionality/acts or implementation involved.

Portions of this invention and corresponding detailed description are presented in terms of software, or algorithms and symbolic representations of operations on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulation of physical quantities. Usually, though not necessarily, these quantities take the form of electrical, magnetic, or optical signals capable of being stored, transferred, combined, compared, and otherwise manipulated. It has proven convenient, principally for reasons of common usage, to refer to these signals as bits, values, elements, symbols, characters, terms, numbers, etc.

It should be borne in mind, however, that all of these and similar terms are to be associated with the appropriate physical quantities and are merely convenient labels applied to these quantities. Unless specifically stated otherwise, or as is apparent from the discussion, terms such as “detecting”, or “calculating”, or “determining”, or “entering”, or “displaying”, or the like, refer to the actions and processes of a computer system, or similar electronic computing device, that manipulate and transform data represented as physical electronic quantities within the computer registers and memories into other data similarly represented as physical quantities within the computer memories or registers, or other such information storage, transmission or display devices.

The software-implemented aspects of the invention are typically encoded on some form of program storage medium or implemented over some type of transmission medium. The program storage medium may be magnetic (e.g., a hard drive), electrical (e.g., flash or DRAM memory), or optical (e.g., a compact disk read only memory, or “CD ROM”), and may be read-only or random access. Similarly, the transmission medium may be conductive wires, optical fiber, radio or other electromagnetic waves, or some other suitable transmission medium known to the art. The invention is not limited by these aspects of any given implementation.

The present invention will now be described with reference to the attached figures. Various structures, systems and devices are schematically depicted in the drawings for purposes of explanation only and so as not to obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. To the extent that a term or phrase is intended to have a special meaning, i.e., a meaning other than that understood by skilled artisans, such a special definition will be expressly set forth in the specification that directly and unequivocally provides the special definition for the term or phrase.

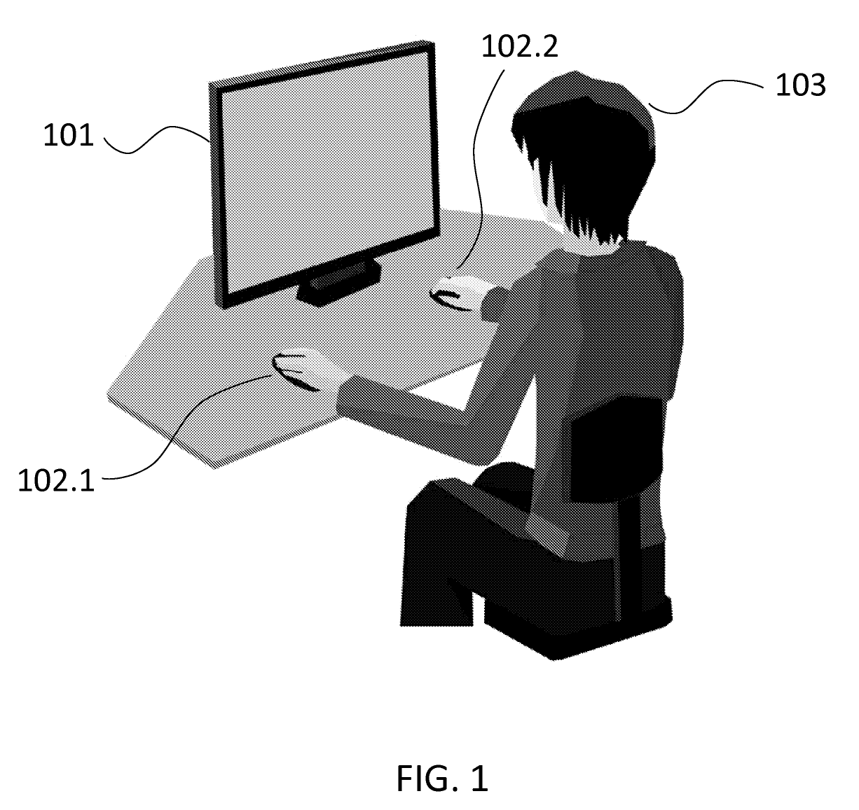

FIG. 1 illustrates an application of the method of entering keyboard characters by an end user according to an embodiment of the present invention. FIG. 1 shows a visual display unit 101, two input agents 102 (a first input agent 102.1 and a second input agent 102.2), a user 103, and a computer processing unit (CPU) (not shown). The visual display unit 101 may be any type of electrical equipment configured to display images generated by the CPU. The visual display unit 101 may be connected to the CPU according to any conventional techniques. The CPU includes a processor configured to carry out instructions based on a computer program, and memory storage configured to store data and/or computer programs such as read-only memory (ROM), hard disk drive (HDD), and/or random access memory (RAM).

Each of the first input agent 102.1 and the second input agent 102.2 may be any type of pointing device or emulator of a pointing device that generates signals according to its displacement by the user 103 (e.g., a mouse) or according to displacement of a user's body part. In other words, each of the first input agent 102.1 and the second input agent 102.2 detects its displacement relative to its supporting surface or detects displacement of a user's body part. Physically, the first input agent 102.1 and the second input agent 102.2 may include an object held under one of the user's hands, with one or more buttons. The first input agent 102.1 and the second input agent 102.2 may feature other elements, such as “wheels”, which allow the user 103 to perform various system-dependent operations, or extra buttons that can add more control or input. Each of the first input agent 102.1 and the second input agent 102.2 may be connected to the CPU according to any conventional techniques. The first input agent 102.1 and the second input agent 102.2 may also be a user's hand itself, the motion of which is monitored by the system. Although illustrated embodiments of the present invention incorporate two input agents 102 (a first input agent 102.1 and a second input agent 102.2), other embodiments may encompass any different number of input agents 102.

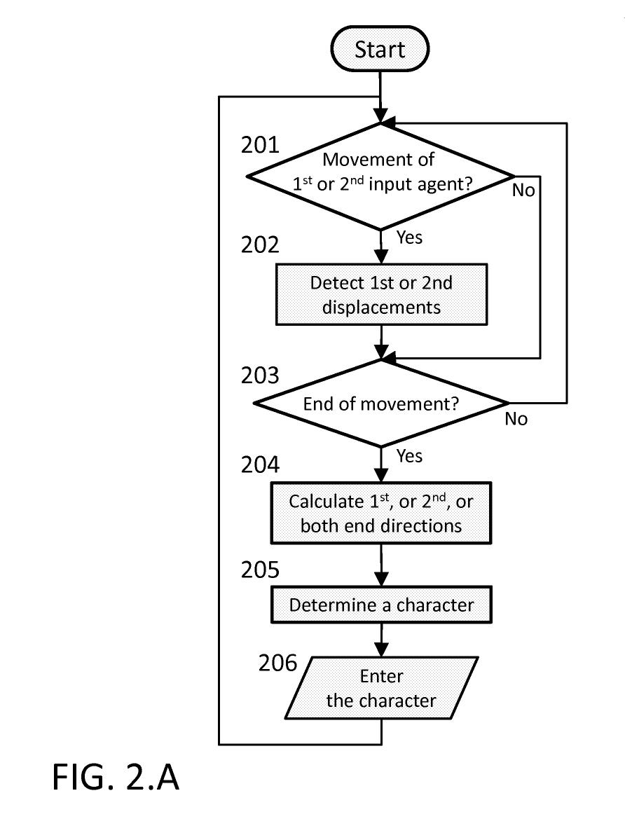

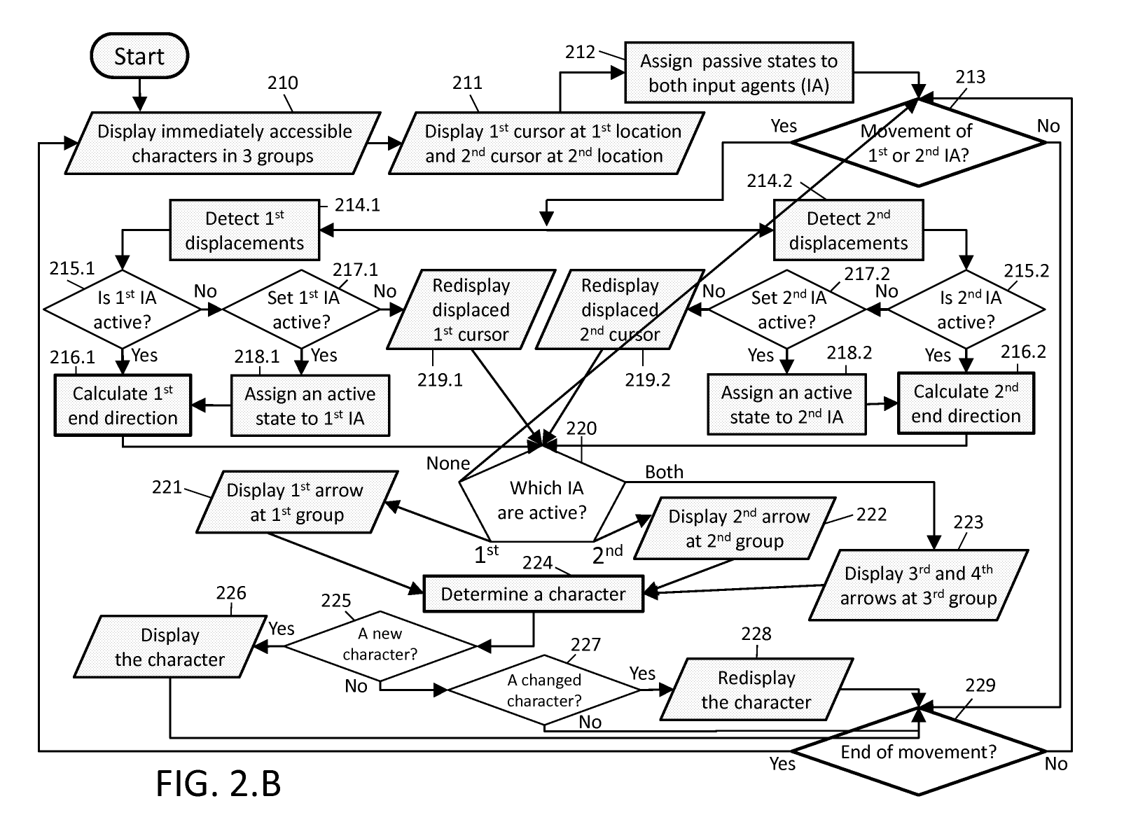

FIG. 2A illustrates a method of entering keyboard characters in an electronic system according to an embodiment of the present invention.

Referring to FIG. 2A, in step 201, the CPU detects movement of at least one of the first input agent 102.1 and the second input agent 102.2. In some embodiments, in step 202, the CPU also detects a plurality of first displacements for the first input agent 102.1 while its movement is being detected. Also, the CPU detects a plurality of second displacements for the second input agent 102.2 while its movement is being detected. For example, if one of the input agents 102 moves, this input agent or a detector that monitors its movement transmits signals which indicate displacement information of the moving input agent to the CPU. The displacement information may include a number array (a vector) that quantifies the orthogonal projections of the displacement of this input agent relative to its position at a previous signal.

In step 203, end of movement of the first and second input agents is determined. For instance, the CPU determines end of movement of the first and second input agents if no movement of the first input agent 102.1 and the second input agent 102.2 is registered continuously for a period of time. The period of time is a non-negative parameter. Tests of a prototype embodiment of this method suggest that a suitable choice for this time parameter for a beginning user is 0.1 sec. This time parameter may be manually adjustable through an options menu or automatically adjustable based on the speed of user's movements, to best accommodate the user's skill and health, for example. It should be realized that a person skilled in the art can propose numerous improvements to the step of determining end of movement of the first and second input agents, e.g., aimed at reducing the transition time between entering two consecutive characters by anticipating the user's intention to stop.

In step 204, when end of movement of the first and second input agents is determined, the CPU calculates at least one of a first end direction and a second end direction. The first end direction characterizes a direction of a last portion of movement of the first input agent 102.1, and the second end direction characterizes a direction of a last portion of movement of the second input agent 102.2. The first end direction may be calculated based on the detected plurality of first displacements that were detected before the end of movement was determined. The second end direction may be calculated based on the detected plurality of second displacement that were detected before the end of movement was determined.

In one embodiment, the calculated first end direction is the direction of the displacement that was detected by the CPU for the first input agent 102.1 last. Similarly, the calculated second end direction is the direction of the displacement that was detected by the CPU for the second input agent 102.2 last.

In another embodiment, the CPU calculates the first end direction by calculating a first sum vector by adding a displacement of the first input agent 102.1 that was detected last with previously detected displacements of the first input agent 102.1 in reverse chronological order until a length of the first sum vector exceeds a threshold value. The calculated first end direction is a direction of the first sum vector. For instance, the CPU takes the last detected displacement vector that was sent by the first input agent 102.1 to the CPU and determines if a length of the vector (which can be inferred from the displacement information) exceeds a threshold value. The threshold value may be any positive value. If the length of the vector of the last detected displacement exceeds the threshold value, the calculated first end direction is the direction of the last detected displacement. If the length of the last detected displacement of the first input agent 102.1 does not exceed the threshold value, then the CPU adds the immediately preceding displacement of the first input agent 102.1 that was received by the CPU before the last detected displacement with the last detected displacement of the first input agent 102.1. If the length of this sum exceeds the threshold value, then the first end direction is the direction of the sum. If the length of this sum does not exceed the threshold value, the CPU continues to add previously detected displacements of the first input agent 102.1 until a length of the resulting sum vector exceeds the threshold value. Once the resulting sum vector exceeds the threshold value, the first end direction is determined as the direction of the resulting sum vector. The same process for calculating a second end direction is applied to the second input agent 102.2, if the second input agent 102.2 moves.

In some embodiments, the first and second end directions, whichever of them are calculated, are further reduced to one of an up end direction, a down end direction, a left end direction, and a right end direction. One of the possible algorithms for this reduction may be to designate a certain span of determined end direction angles around the strictly upward direction to be reduced to the “up direction”, another span of determined end direction angles around the strictly rightward direction to be reduced to the “right direction”. Similar methods are used for the “down direction” and the “left direction”.

Next, in step 205, the CPU determines the keyboard character from a plurality of keyboard characters based on at least one of the calculated (reduced) first end direction and the calculated (reduced) second end direction. For example, an ordered pair [D₁, D₂] is generated based on non-movement or the calculated first end direction of the first input agent 102.1 and non-movement or the calculated second end direction of the second input agent 102.2. For example, D₁ corresponds to a passive state if no movement of the first input agent 102.1 was detected by determining end of movement in step 203. Otherwise, D₁ corresponds to an active state such as one of the up end direction, the down end direction, the right end direction, and the left end direction of the first input agent 102.1. D₂ corresponds to the passive state or an active state such as the up, down, right, or left end directions of the second input agent 102.2. The values of D₁ and D₂ may include discrete values such as 0, 1, 2, 3, and 4, for example, or any other type of values. Based on the values of D₁ and D₂, the CPU determines a keyboard character among a plurality of keyboard characters, which is explained below. After the keyboard character is determined according to the values of D₁ and D₂, in step 206, the CPU enters the keyboard character into the electronic system. Although example embodiments of the present invention show the values of D₁ and D₂ as each ranging over five possible states, embodiments of the present invention also encompass situations where the values of D₁ and D₂ range over any different number of states.

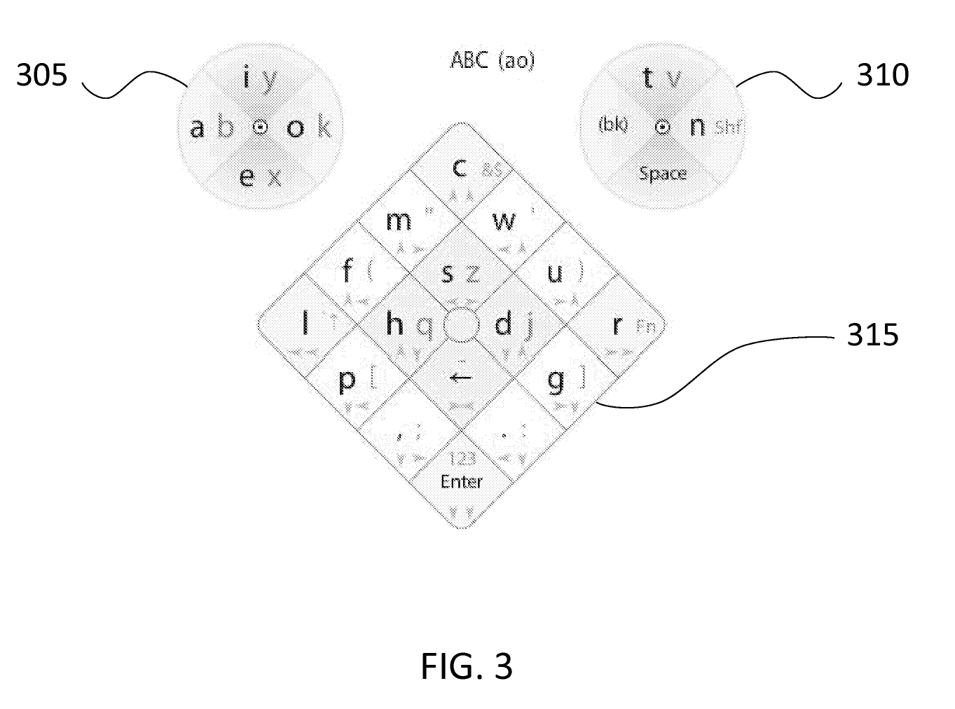

FIG. 2B and accompanying FIGS. 3-5 illustrate a method of entering keyboard characters in an electronic system according to another embodiment of the present invention.

In step 210 of FIG. 2B, the CPU displays a first group of keyboard characters, a second group of keyboard characters, and a third group of keyboard characters on the visual display unit 101 at the start of typing, or at the start of typing of a new character after determining end of movement. This displaying step 210 is illustrated in FIG. 3, discussed next.

FIG. 3 is a screenshot of a plurality of keyboard characters displayed on the visual display unit 101 at the start of typing or at the start of typing of a new character according to an embodiment of the present invention. For example, the CPU displays a first group of keyboard characters 305, a second group of keyboard characters 310, and a third group of keyboard characters 315 on the visual display unit 101.

The first group 305 corresponds to the first input agent 102.1 in the active state and the second input agent 102.2 in the passive state, the second group 310 corresponds to the second input agent 102.2 in the active state and the first input agent 102.1 in the passive state and the third group 315 corresponds to both the first input agent 102.1 and the second input agent 102.2 in the active states.

The first group 305 is divided into a plurality of sections. In this embodiment, each section corresponds to at least two keyboard characters. For example, in the top section of the first group 305, two keyboard characters—“i” and “y”—are displayed. One of the two keyboard characters is emphasized. In this example, the letter “i” is emphasized (bolded) and the letter “y” is de-emphasized (faded). The other sections in the first group 305 similarly include two keyboard characters, one of which is emphasized. The user 103 can switch between a layout “screen” that emphasizes the first set of keyboard characters, whereupon the first set of characters is typed (main letter layout), and a layout screen that emphasizes the second set of keyboard characters, whereupon the second set of characters is typed (extended letter layout). This feature is further explained later in the specification.

Similarly, the second group 310 and the third group 315 are divided into a plurality of sections. Most of these sections are similar to the section described above with reference to the first group 305. They display two keyboard characters, which may include standard control characters such as “Shift” or “Enter”. The exceptional left section “(bk)” in the second group 310 and the four corner sections in the third group 315 relate to switching between layout screens and will be explained later.

Referring back to FIG. 2B, in step 211, a first cursor is displayed in the first group 305 and a second cursor is displayed in the second group 310. For example, the CPU positions the first cursor for the first input agent 102.1 in the middle of the circle of the first group 305 irrespective of a physical location of the first input agent 102.1 and positions the second cursor for the second input agent 102.2 in the middle of the circle of the second group 310 irrespective of a physical location of the second input agent 102.2.

In the considered embodiment, illustrated by FIG. 2B, each of the first input agent 102.1 and the second input agent 102.2 is assigned either a passive state or an active state. These assignments generally change in the process of typing with the presented method as explained below. The assignment of states may be implemented as the CPU keeping track of two variables in the computer memory whose values (e.g., ranging through “false” and “true”) correspond to a passive state and an active state of the respective input agent. The CPU may change the values of the variables to reflect the change of the states assigned to the first input agent 102.1 and the second input agent 102.2.

In step 212 of FIG. 2B, both the first input agent 102.1 and the second input agent 102.2 are assigned passive states at the start of a keyboard character selection.

Next, in step 213, movement of at least one of the first input agent 102.1 and the second input agent 102.2 is detected. This step 213 is the same as step 201 described in FIG. 2A.

If in step 213 movement of the first input agent 102.1 is detected, then the CPU executes the sequence of steps beginning from step 214.1 as described below. Likewise, if in step 213 movement of the second input agent 102.2 is detected, then the CPU executes the sequence beginning from step 214.2. Otherwise, the CPU performs determining end of movement step 229, analogous to step 203 in FIG. 2A.

In step 214.1, executed if the CPU detects movement of the first input agent 102.1, the CPU detects the plurality of first displacements as described with reference to step 202 in FIG. 2A.

Then, in step 215.1, the CPU checks whether the first input agent 102.1 is in the active state or in the passive state. If the first input agent 102.1 is in the active state (is “active”) then, in step 216.1, the CPU calculates the first end direction as described with reference to step 204 in FIG. 2A. The calculated first end direction may further be reduced to one of an up direction, a down direction, a left direction, and a right direction as described with reference to step 204 in FIG. 2A. If the first input agent is in the passive state (is “passive”) then, in step 217.1, the CPU determines whether to set the first input agent to an active state based on the displacement of the first input agent 102.1.

For example, in step 217.1, the CPU may verify whether the first cursor for the first input agent 102.1 has reached the border of its circle in the first group 305 in FIG. 3. If it has then, in step 218.1, the CPU sets the first input agent 102.1 to the active state, and the process continues to step 216.1 to calculate the first end direction. However, if in step 217.1, the CPU determines not to set the first input agent 102.1 active because the first cursor has not reached the border of its circle in the first group 305 then, in step 219.1, the CPU redisplays the first cursor within the circle in the first group 305 to reflect the detected displacement of the first input agent 102.1.

Because steps 214.2-219.2 relating to the second input agent 102.2 are analogous to steps 214.1-219.1, the details are omitted for the sake of brevity.

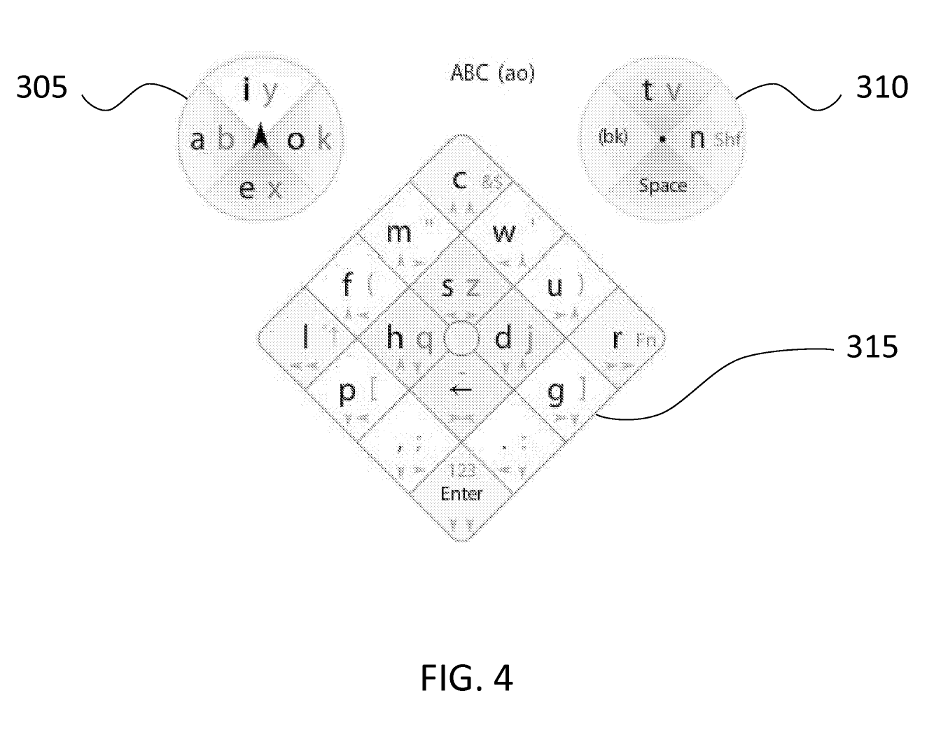

In step 220, the CPU determines which of the first input agent 102.1 and the second input agent 102.2 are active. If neither of the first input agent 102.1 and the second input agent 102.2 is active, the process returns to step 213 to detect movement of the first input agent 102.1 or the second input agent 102.2. If the first input agent 102.1 is active and the second input agent 102.2 is passive, in step 221, the CPU displays a first arrow in the first group 305, as discussed with reference to FIG. 4 next.

FIG. 4 shows the first group 305, the second group 310, and the third group 315 when the first input agent 102.1 is in the active state (is active) and the second input agent 102.2 is in the passive state (is passive) according to embodiments of the present invention. To indicate that the first input agent 102.1 is active and the second input agent 102.2 is passive, the CPU displays a first arrow in the first group 305 instead of the first cursor. The first arrow indicates the current (reduced) first end direction. After the first input agent 102.1 is assigned the active state, the first cursor is not displayed and it plays no role in subsequent character selection. While the second input agent 102.2 is in the passive state, the second cursor for the second input agent is displayed in the second group 310. As soon as the first input agent 102.1 becomes active, the radius of the circle in the second group 310 (as shown in FIG. 3) may be reduced. As a result, the second input agent 102.2 may be activated, i.e. switched from passive to active, by a smaller displacement than when both the first input agent 102.1 and the second input agent 102.2 were in passive states.

Referring back to FIG. 2B, in step 222, when the second input agent 102.2 is active and the first input agent 102.1 is passive, the CPU displays a second arrow in the second group 310. The operational and displaying steps described in the previous paragraph then apply analogously to this situation with the labels “first” and “second” being interchanged.

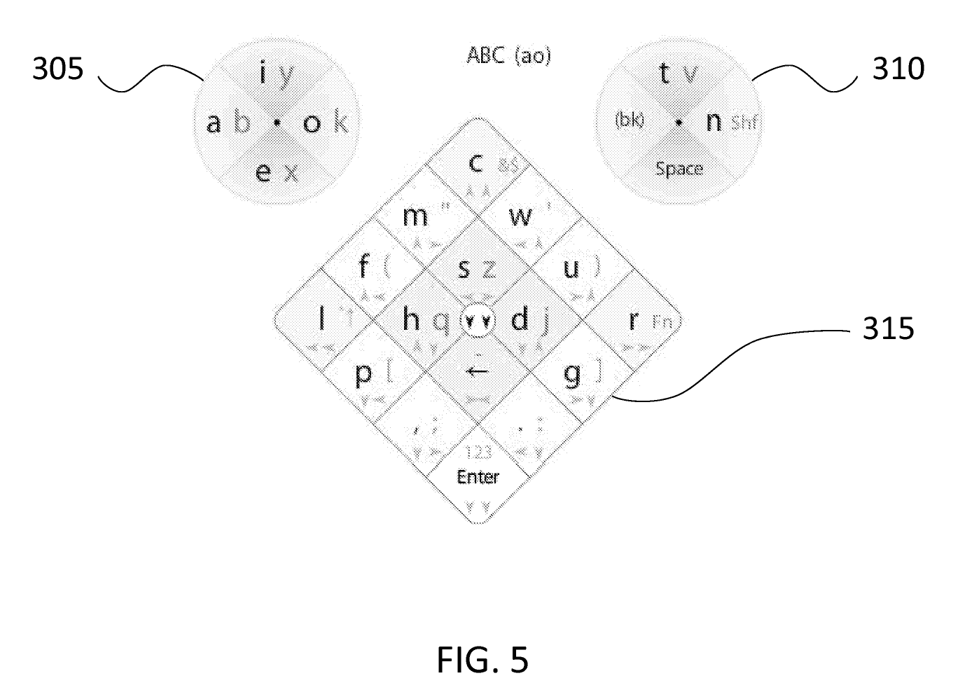

In step 223, if both the first input agent 102.1 and the second input agent 102.2 are active, the CPU displays third and fourth arrows in the third group 315, as shown in FIG. 5 and described next.

FIG. 5 shows the first group 305, the second group 310, and the third group 315 when the first input agent 102.1 and the second input agent 102.2 are active according to embodiments of the present invention. In this case, the CPU displays a third arrow and a fourth arrow in the third group 315. The displayed third arrow and fourth arrows indicate the first and second end directions, calculated in steps 216.1 and 216.2.

Referring back to FIG. 2B, in step 224, the CPU determines a keyboard character from the plurality of keyboard characters displayed in the first group 305, the second group 310, and the third group 315 based on the current pair of end directions [D₁, D₂], as described with reference to step 205 in FIG. 2A and illustrated below.

At the first determination of a keyboard character, i.e., at the first execution of step 224 since the start of typing of a new character, the keyboard character that corresponds to the current pair [D₁, D₂] may immediately be displayed as typed text (steps 225-226), offering a feedback to the user 103.

At the subsequent determinations of a keyboard character before end of movement of the first and second input agents is determined (further step 229), in step 227, the CPU compares the currently determined character with the previously determined character. If the CPU recognized a change of the determined character, then the displayed and typed character is replaced by an updated character, step 228. For example, the current pair [D₁, D₂] and the respective keyboard character would change if a passive input agent 102 also activates, or if the determined end direction of any active input agent 102 changes.

In step 229, the CPU determines end of movement of the first and second input agents, which is similar to step 203 in FIG. 2A. Once the end of movement of the first and second input agents is determined, steps 210-212 are repeated: both the first input agent 102.1 and the second input agent 102.2 are assigned the passive states and their respective cursors are reset to the respective predetermined positions and are surrounded each by their respective circles, as shown in FIG. 3.

For example, after a keyboard character is typed, the CPU displays the screenshot in FIG. 3. Then, if the user 103 wishes to type the letter “i”, the user can move the first input agent 102.1 upward and not move the second input agent 102.2. After the first input agent 102.1 becomes active, while it is in motion, the CPU displays the screen shot in FIG. 4 and the letter “i” appears in the text field to which the text is ultimately typed. If, for example, the user 103 has erroneously moved the first input agent 102.1 in a direction that sufficiently deviates from the upward direction and is recognized as a right end direction, a letter “o” appears in the text field instead. Then while the first input agent 102.1 moves, the user 103 can correct his direction of movement to an upward direction. As soon as the determined first end direction changes from “right” to “up”, the letter “o” is deleted from the text field and the letter “i” is displaced instead. When the first input agent 102.1 stops, the CPU displays the screen shot shown in FIG. 3.

In another example, if the user 103 wishes to type “Enter”, the user 103 moves both the first input agent 102.1 and the second input agent 102.2 downward. While both the first input agent 102.1 and the second input agent 102.2 are in motion, the CPU displays the screenshot shown in FIG. 5. The displaying picture remains unchanged even if one input agent 102 stops but the other continues the downward movement. When both the first input agent 102.1 and the second input agent 102.2 stop moving, “Enter” is typed and the CPU again displays the screenshot in FIG. 3.

Now, an optimized keyboard layout according to embodiments of the present invention is explained. For example, as stated above, a typed keyboard character corresponds to an ordered pair of discrete directions [D₁, D₂], where D₁ and D₂ may include five possibilities: passive state, the up end direction, the down end direction, the left end direction, and the right end direction. Because only 5²−1=24 pairs (excluding the pair with D₁=D₂=passive) are available for typing, example embodiments of the present invention use several switchable layout maps, as explained below.

Referring to the screenshots in FIGS. 3-5, two different layout maps are illustrated in these figures—a main letter map and an extended letter map. For example, the main letter map includes the emphasized (bolded) keyboard character in each of the sections of the first group 305, the second group 310, and the third group 315. The extended letter map includes the de-emphasized (faded) keyboard character in each of the sections of the first group 305, the second group 310, and the third group 315. The user 103 may switch between these two different layout maps, as explained next.

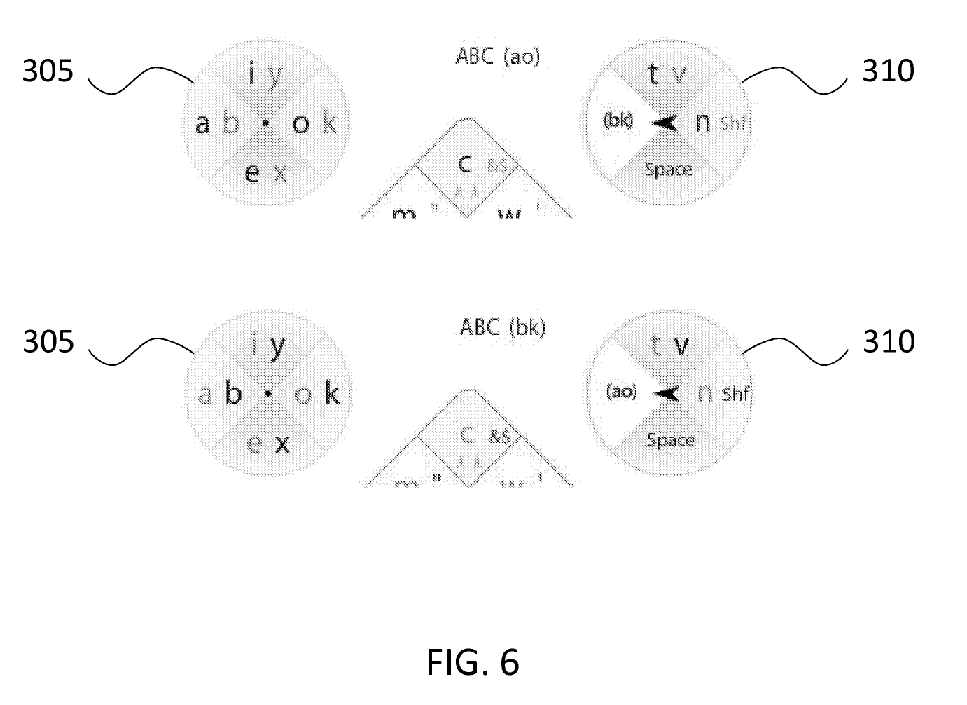

FIG. 6 illustrates switching between the main letter map and the extended letter map according to an embodiment of the present invention. For example, FIG. 6 shows the first group 305 and the second group 310. As stated above, the first character in each two-character sector belongs to the main letter map and the second character in each two-character sector belongs to the extended letter map. In this example, the user 103 can switch from the main letter map to the extended letter map by selecting [D₁=passive, D₂=left]. In other words, the user 103 moves the second input agent 102.2 leftward then stops it, and does not move the first input agent 102.1. As a result, the ordered pair [passive, left] is generated, and the layout map is switched from the main letter map to the extended letter map, as shown in the bottom panel of FIG. 6. After switching as described, in the first group 305 and the second group 310 of the bottom panel of FIG. 6, the previously de-emphasized keyboard characters are now emphasized, and, vice versa, the previously emphasized keyboard characters are now de-emphasized in every section. As a result, the user 103 is now able to select the letters “y”, “b”, “k”, “x”, “v”, among others, for example.

The switching between different layout maps may be performed by movements of the first and/or second input agents 102 (e.g., generating an ordered pair) as described above. The switching may also/instead be performed by other means. For instance, the user 103 may switch between the main and extended letter maps based on an independent signal from either at least one of the first input agent 102.1 and the second input agent 102.2, or a signal from a source unrelated to the first input agent 102.1 and the second input agent 102.2. For example, the user 103 may switch the maps by clicking one or more mouse buttons, or, if the input agents 102 are embodied by a wheel mouse, by rotating either the first or the second mouse wheel.

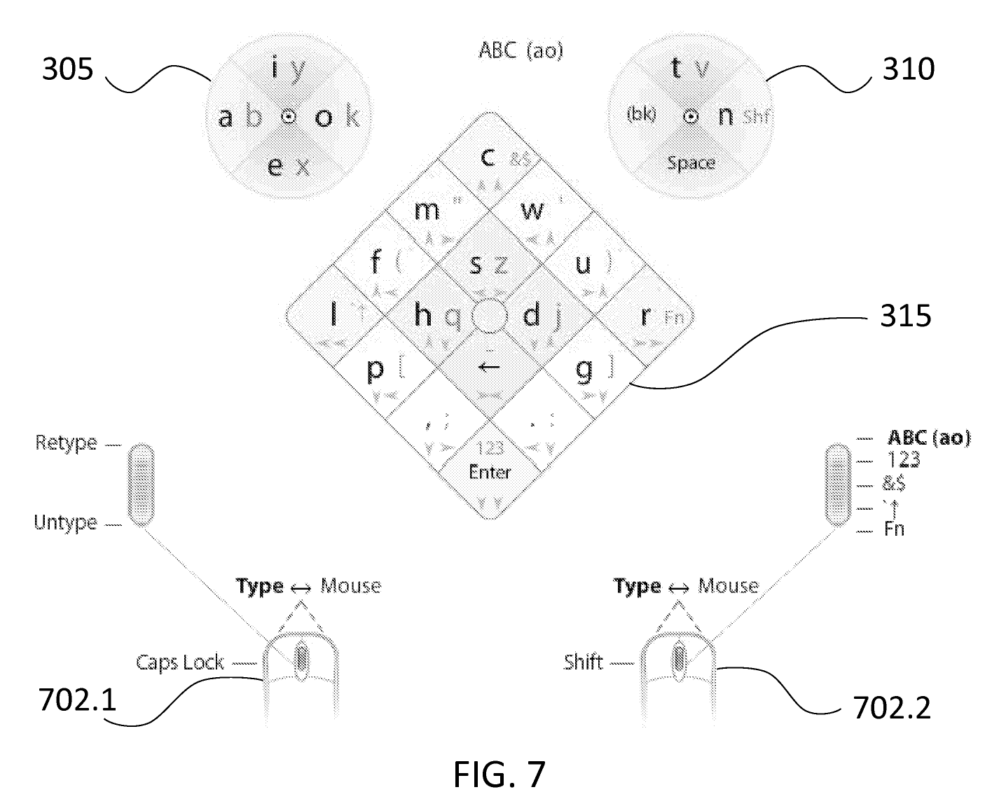

FIG. 7 illustrates a main letter layout map and an extended letter layout map according to an embodiment of the present invention. For example, FIG. 7 illustrates the first group 305, the second group 310, and the third group 315. In addition, FIG. 7 shows displayed picture images of the first input agent 702.1 and the second input agent 702.2. These images provide visual reference for the user 103 to auxiliary functions that may be performed by the optional buttons and wheels of the first input agent 102.1 and the second input agent 102.2.

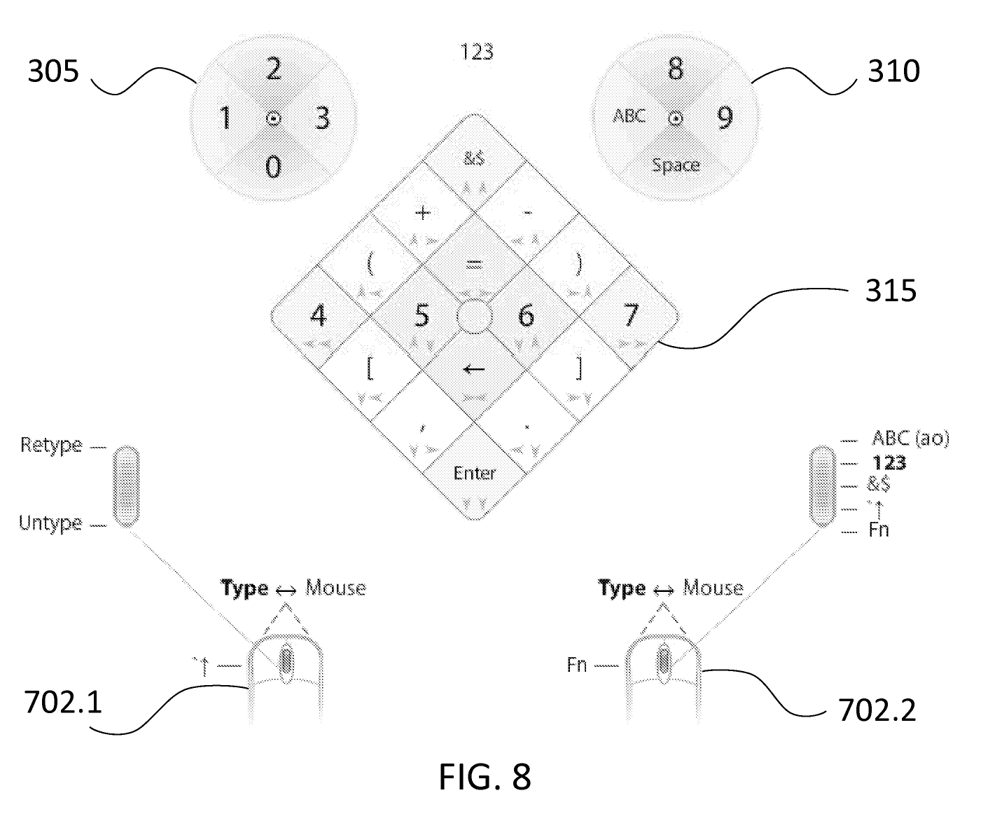

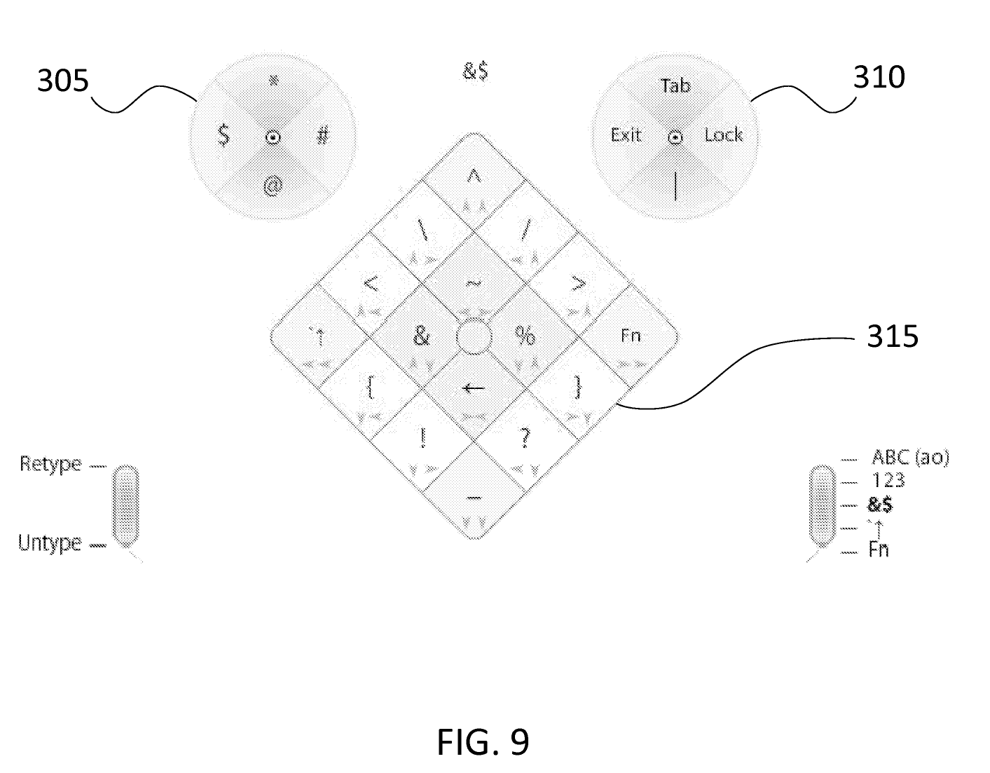

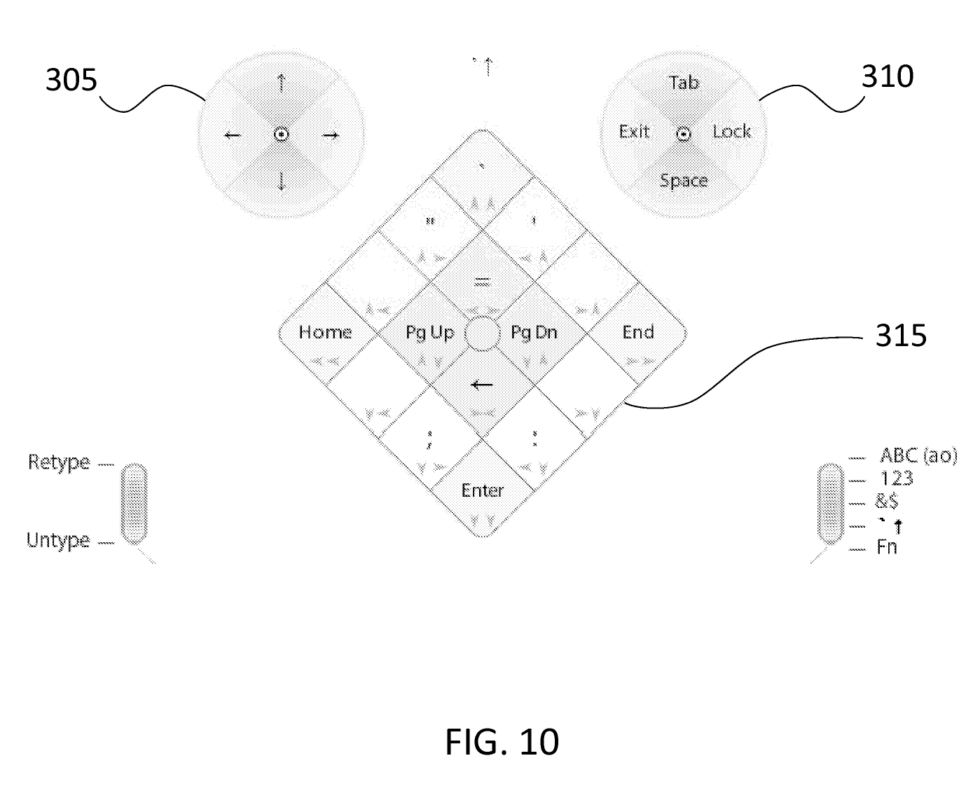

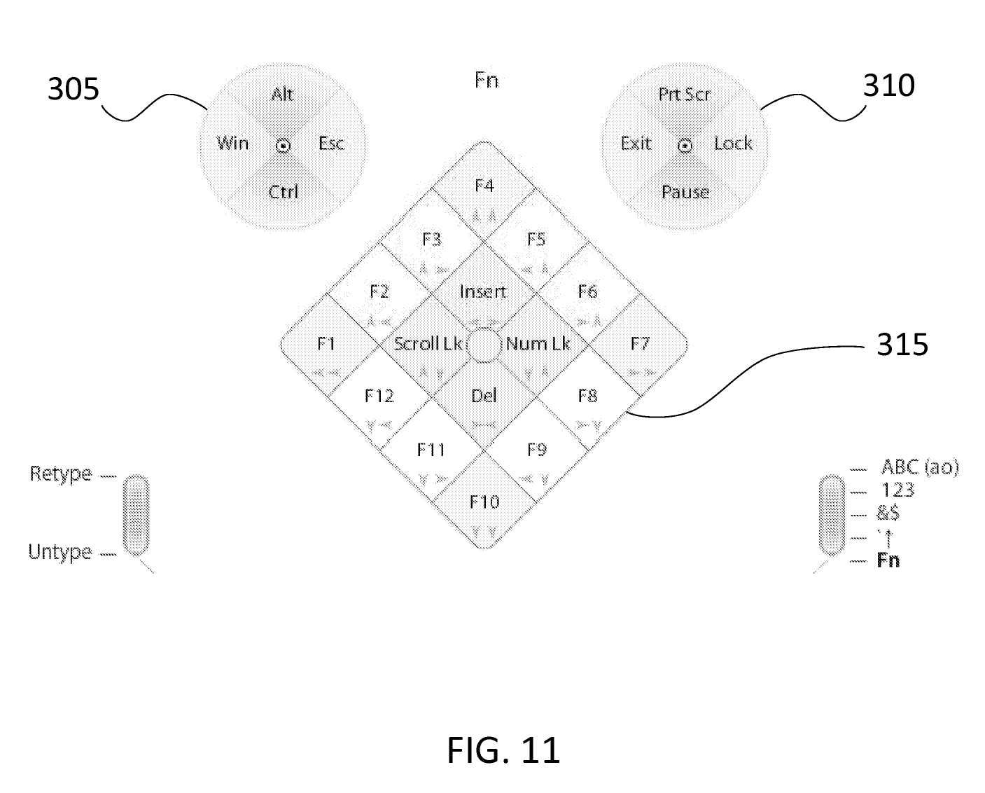

For example, the user 103 may switch the layout maps by rotating the wheel on the second input agent 102.2. In the embodiment illustrated by FIG. 7, rotation of the right wheel cycles through five entry screens: letters (FIG. 7), numbers (FIG. 8), symbols (FIG. 9), directional symbols (FIG. 10), and functions (FIG. 11).

In an embodiment shown in FIG. 7, the user 103 may also retype the last typed letter or delete the last typed text by rotating the wheel on the first input agent 102.1. In addition, the user 103 may enable the “Caps Lock” and “Shift” functions by pressing the left button on the first input agent 102.1 and the second input agent 102.2 respectively. Similarly, other standard functions, such as “Control”, “Alt”, etc., may be associated with rotating wheels, or pressing buttons or their combinations on the first input agent 102.1 and the second input agent 102.2.

The character arrangement on the main letter layout and the extended letter layout shown in FIG. 7 is optimized by character frequency. For example, in the main letter layout, the first group 305 and the second group 310 include seven keyboard characters that occur in English texts most frequently: “space”, “e”, “t”, “a”, “o”, “i”, “n”. The remaining, eighth character of the first group 305 and the second group 310 is the switch to the extended letter layout “(bk)”, which should be invoked with comparable frequently during typing with this embodiment of the method. The other layout keys are likewise grouped by accessibility classes. The higher the accessibility class, the higher the frequency of the keyboard characters that populate that class. For instance, a first class consists of the eight main layout keys of the first group 305 and the second group 310. The first class is populated by the aforementioned eight most frequently used characters. A second class consists of eight symmetric pairs on the main layout of the third group 315 such as [left, right], [up, down], and [left, left], for example. The second class is populated by the next eight most frequently used characters: “s”, “h”, “r”, “d”, “l”, “c”, and “Enter”. A third class consists of eight asymmetric pairs on the main letter layout of the third group 315 such as [up, right] and [down, right], for example. A fourth class consists of eight keys of the first group 305 and the second group 310 on the extended layout. A fifth class consists of eight symmetric pairs on the extended layout of the third group 315. A sixth class consists of eight asymmetric pairs on the extended layout of the third group 315. With the above keyboard arrangement, the user 103 can significantly increase his/her typing speed. Also, mutual arrangement of the letters “e”, “t”, and “h” facilitates typing of the most frequent English bigrams such as “th” and “he”, for example.

Furthermore, the keyboard characters in the layout shown in FIG. 7 are also arranged to facilitate easy remembering of the layout, in particular, for natural touch typing. The vowels and consonants on the main letter layout in the first group 305 and the second group 310 are separated, the vowels being in the first group and the consonants in the second group. Also, some keyboard characters are arranged so that the directions of movement of the first and second input agents 102 are implied by the characters (e.g., “l”—left, “r”—right, and “c”—center). The direction of movement for some other keyboard characters (e.g., for h, q, d, j, s, z, p, g, and f) may be suggested by the form of the keyboard characters. Keyboard characters similar in sound, shape, or alphabetic position tend to appear in symmetric groups (e.g., a-b, a-o, e-i-y, x-y, s-z, and m-w). Also, keyboard characters similar in shape, alphabetic position, or function may share the same direction (e.g., “n”—[passive, right] and “m”—[up, right] share the second “right” direction; or “space”—[passive, down], “.”—[left, down], and “enter”—[down, down] share the second “down” direction).

In a preferred embodiment, the main letter layout map is illustrated in FIG. 7. This map includes the correspondence between pairs [D₁, D₂] and keyboard letter characters that is given by Table 1. The main letter layout map includes first values (D₁), second values (D₂), and corresponding letter input choices. The first values indicate a passive state or a first direction. The second values indicate a passive state or a second direction. The first and second values form an ordered pair [D₁, D₂]. Such a pair is mapped to a keyboard character as illustrated.

TABLE 1

| | 2^{nd} value | | | | |
|---|---|---|---|---|---|
| 1^{st} value | Passive | Up | Down | Left | Right |
| Passive | | t | | | n |
| Up | i | c | h | f | m |
| Down | e | d | | p | |
| Left | a | w | | l | s |
| Right | o | u | g | | r |

For example, the CPU determines the input choice based on the main letter map as follows. As shown in FIG. 7 or in Table 1, the determined input choice is t if the first value indicates the passive state and the second value indicates the up direction, the determined input choice is n if the first value indicates the passive state and the second value indicates the right direction, and analogously for the other pairs of the first and second values as should be inferred from Table 1 and will not be described in this text for brevity.

Furthermore, the user 103 may switch between the main letter map, described above, to an extended letter map based on at least one of the first value, the second value, or an input signal independent from the first and second values, as described above, for example. In a preferred embodiment, the extended letter layout map is illustrated in FIG. 7 and includes the correspondence between pairs [D₁, D₂] and keyboard characters that is given by Table 2.

TABLE 2

| | 2^{nd} value | | | | |
|---|---|---|---|---|---|
| 1^{st} value | Passive | Up | Down | Left | Right |
| Passive | | v | | | |
| Up | y | | q | | |
| Down | x | j | | | |
| Left | b | | | | z |
| Right | k | | | | |

For example, as shown in FIG. 7 or in Table 2, when the CPU determines the input choice based on the extended letter map, the determined input choice is v if the first value indicates a passive state and the second value indicates the up direction, and analogously for the other pairs of the first and second values as should be inferred from Table 2 and will not be described in this text for brevity.

FIG. 8 illustrates a number map according to embodiments of the present invention. For example, FIG. 8 illustrates the first group 305, the second group 310, and the third group 315. In addition, FIG. 8 shows displayed picture images of the first input agent 702.1 and the second input agent 702.2. The number map includes the correspondence between pairs [D₁, D₂] and keyboard characters that is given by Table 3.

TABLE 3

| | 2^{nd} value | | | | |
|---|---|---|---|---|---|
| 1^{st} value | Passive | Up | Down | Left | Right |
| Passive | | 8 | | | 9 |
| Up | 2 | | 5 | | |
| Down | 0 | 6 | | | |
| Left | 1 | | | 4 | |
| Right | 3 | | | | 7 |

Similar to Tables 1 and 2, the number map includes first values, second values and corresponding number input choices. The first values indicate a passive state or a first direction. The second values indicate a passive state or a second direction. The first and second values form an ordered pair of directions [D₁, D₂] as described above. Such a pair is mapped to a keyboard character according to Table 3.

Referring to FIG. 8 and Table 3, the determined input choice is 1 if the first value indicates the left direction and the second value indicates a passive state, and analogously for the other pairs of the first and second values as should be inferred from Table 3 and will not be described in this text for brevity.

The user 103 may switch between the main letter map and the number map based on at least one of the first value, the second value, or an input signal independent from the first and second values. For example, in the illustrated embodiment the user 103 may switch by rotating the wheel on the second input agent 102.2, as described above.

Referring to FIG. 8, the user 103 may further switch to entering directional symbol keys (FIG. 10) by pressing the left button on the first input agent 102.1 as illustrated in FIG. 8 by a label at the displayed picture image of the first input agent 702.1. The user 103 may also or switch to entering function keys (FIG. 11) by pressing the left button on the second input agent 102.2 as illustrated in FIG. 8 by a label at the displayed picture image of the second input agent 702.2. Furthermore, the user 103 may switch to any of the five entry screens by rotating the wheel on the second input agent 102.2.

FIG. 9 illustrates a screenshot showing a symbol map according to an embodiment of the present invention. For example, FIG. 9 illustrates the first group 305, the second group 310, and the third group 315. Similar to the layout maps described above, the symbol map includes first values, second values and corresponding input choices. Although a table is not given with respect to this figure, an example symbol map from the first and second values to the corresponding input choices is evident from the sections in the first group 305, the second group 310, and the third group 315 shown in FIG. 9. For example, if the first value is the left direction and the second value is the passive state, the corresponding input choice is the symbol “$”.

FIG. 10 illustrates a directional symbol map according to an embodiment of the present invention. The directional symbol map includes features similar to the features described above. Therefore, the details are omitted for the sake of brevity.

FIG. 11 illustrates a function map according to an embodiment of the present invention. The function map includes features similar to the features described above. Therefore, the details are omitted for the sake of brevity.

While embodiments of the method should not be limited by any of prospective practical advantages listed below, the advantages over the prior art may include the following. The selection of a keyboard character with input agents 102 does not need to rely on the position of the input agents 102, the location a cursor on the visual display unit 101, or the past path of the cursor. The user 103 does not need to identify the location of an image of a key on the visual display unit 101, move the cursor onto the key image, stop the cursor within the image borders, and perform an additional action for entering the keyboard character. As demonstrated by the above descriptions, the user 103 may communicate the information necessary for selecting the keyboard character solely by the direction of the last portion of movement of the input agents 102, thus entering the keyboard character with a minimal amount of physical motion. Furthermore, after entering a keyboard character, the user 103 does not need to move an input agent back. Rather, the user 103 can immediately proceed to entering a new keyboard character, thus saving more time and muscular effort. Embodiments of the present invention may lead to relieved physical strain on user's hands, especially on fingers, and to increased speed of typing. The user 103 may also remain sufficiently unconstrained in his/her motion because the user 103 may move the inputs agents 102 freely as long as he/she properly directs the inputs agents 102 before stopping them. Furthermore, the described embodiments may allow the user 103 to enter keyboard characters with regular pointing devices or other input agents without the need to coordinate his/her motion with a visual feedback away from the text field. As a result, the user 103 can naturally “touch-type”, looking at the text typed instead of the keyboard layout.

Variations of the example embodiments of the present invention are not to be regarded as a departure from the spirit and scope of the example embodiments of the invention, and all such variations that would be apparent to one skilled in the art are intended to be included within the scope of this invention.

What is claimed is:

1. A method of entering keyboard characters in an electronic system, the method comprising:
detecting movement of at least one of a first input agent and a second input agent;
calculating at least one of (1) a first end direction that characterizes direction of a last portion of movement of the first input agent, and (2) a second end direction that characterizes direction of a last portion of movement of the second input agent;
determining end of movement of the first and second input agents; and
determining a keyboard character from a plurality of keyboard characters based on at least one of the calculated first end direction and the calculated second end direction.

2. The method of claim 1, further comprising:
detecting at least one of (1) a plurality of first displacements for the first input agent while movement is being detected for the first input agent and (2) a plurality of second displacements for the second input agent while movement is being detected for the second input agent,
wherein calculating the first end direction is based on the detected plurality of first displacements, and calculating the second end direction is based on the detected plurality of second displacements.

3. The method of claim 2, wherein
the calculated first end direction is a direction of a displacement of the first input agent that was detected last, and
the calculated second end direction is a direction of a displacement of the second input agent that was detected last.

4. The method of claim 2, wherein
the calculating the first end direction step includes calculating a first sum vector by adding a displacement of the first input agent that was detected last with previously detected displacements of the first input agent in reverse chronological order until a length of the first sum vector exceeds a threshold value, wherein the calculated first end direction is a direction of the first sum vector;
the calculating the second end direction step includes calculating a second sum vector by adding a displacement of the second input agent that was detected last with previously detected displacements of the second input agent in reverse chronological order until a length of the second sum vector exceeds a threshold value, wherein the calculated second end direction is a direction of the second sum vector.

5. The method of claim 1, further comprising:
reducing each of the calculated first and second end directions to one of an up direction, a down direction, a left direction, and a right direction.

6. The method of claim 1, wherein the determining end of movement of the first and second input agents step includes:
registering no movement of the first input agent and the second input agent continuously for a period of time, the period of time being a non-negative parameter.

7. The method of claim 1, further comprising:
assigning a state to each of the first input agent and the second input agent from a plurality of states, the plurality of states including a passive state and an active state, wherein
if the first input agent is assigned the active state and the second input agent is assigned the passive state when the end of movement is determined, then the keyboard character is determined based on at least the calculated first end direction;
if the first input agent is assigned the passive state and the second input agent is assigned the active state when the end of movement is determined, then the keyboard character is determined based on at least the calculated second end direction;
if the first input agent is assigned the active state and the second input agent is assigned the active state when the end of movement is determined, then the keyboard character is determined based on at least the calculated first end direction and the calculated second end direction.

8. The method of claim 7, further comprising:
displaying at least some of the plurality of keyboard characters.

9. The method of claim 8, wherein the displaying step includes:
displaying a first group of keyboard characters corresponding to the first input agent being in the active state and the second input agent being in the passive state;
displaying a second group of keyboard characters corresponding to the second input agent being in the active state and the first input agent being in the passive state; and
a third group of keyboard characters corresponding to both the first and second input agents being in the active states.

10. The method of claim 9, wherein the displaying step includes:
displaying a first cursor for the first input agent in the first group after a previous input choice is entered, wherein the first cursor is positioned to a first location irrespective of a position of the first input agent; and
displaying a second cursor for the second input agent in the second group after a previous input choice is entered, wherein the second cursor is positioned to a second location irrespective of a position of the second input agent.

11. The method of claim 10, further comprising:
displaying a first arrow in the first group instead of the first cursor when the first input agent is in the active state and the second input agent is in the passive state, the first arrow indicating a current first end direction;
displaying a second arrow in the second group instead of the second cursor when the first input agent is in the passive state and the second input agent is in the active state, the second arrow indicating a current second end direction; and
displaying third and fourth arrows in the third group when the first and second input agents are in the active states, the third arrow indicating a current first end direction, and the fourth arrow indicating a current second end direction.

12. The method of claim 1, further comprising:
displaying the determined keyboard character in a typing field, the typing field either displayed by the method or being a text display field of an independent application to which the keyboard characters are entered;
redisplaying the determined keyboard character in the typing field if the determined keyboard character changes before a completion of current character entering.

13. A method of entering keyboard characters in an electronic system, the method comprising:
generating a first value indicating one of a passive state, an up direction, a down direction, a left direction, and a right direction;
generating a second value indicating one of a passive state, an up direction, a down direction, a left direction, and a right direction;
determining the keyboard character from a plurality of keyboard characters based on at least the generated first value, the generated second value, and a main letter map, the main letter map including:
the determined input choice is t if the first value indicates the passive state and the second value indicates the up direction,
the determined input choice is n if the first value indicates the passive state and the second value indicates the right direction,
the determined input choice is i if the first value indicates the up direction and the second value indicates the passive state,
the determined input choice is c if the first value indicates the up direction and the second value indicates the up direction,
the determined input choice is h if the first value indicates the up direction and the second value indicates the down direction,
the determined input choice is f if the first value indicates the up direction, and the second value indicates the left direction,
the determined input choice is m is the first value indicates the up direction, and the second value indicates the right direction,
the determined input choice is e if the first value indicates the down direction, and the second value indicates the passive state,
the determined input choice is d if the first value indicates the down direction, and the second value indicates the up direction,
the determined input choice is p if the first value indicates the down direction and the second value indicates the left direction,
the determined input choice is a if the first value indicates the left direction and the second value indicates the passive state,
the determined input choice is w if the first value indicates the left direction and the second value indicates the up direction,
the determined input choice is l if the first value indicates the left direction, and the second value indicates the left direction,
the determined input choice is s if the first value indicates the left direction and the second value indicates the right direction,
the determined input choice is o if the first value indicates the right direction and the second value indicates the passive state,
the determined input choice is u if the first value indicates the right direction and the second value indicates the up direction,
the determined input choice is g if the first value indicates the right direction and the second value indicates the down direction,
the determined input choice is r if the first value indicates the right direction and the second value indicates the right direction.

14. The method of claim 13, further comprising:
switching among the main letter map and an extended letter map, the switching based on at least one of (1) the first value, (2) the second value, or (3) an input signal independent from the first and second values;
the extended letter map including:
the determined input choice is v if the first value indicates the passive state and the second value indicates the up direction,
the determined input choice is y if the first value indicates the up direction and the second value indicates the passive state,
the determined input choice is q is the first value indicates the up direction and the second value indicates the down direction,
the determined input choice is x is the first value indicates the down direction, and the second value indicates the passive state,
the determined input choice is j is the first value indicates the down direction and the second value indicates the up direction,
the determined input choice is b is the first value indicates the left direction and the second value indicates the passive state,
the determined input choice is z is the first value indicates the left direction and the second value indicates the right direction,
the determined input choice is k if the first value indicates the right direction and the second value indicates the passive state.

15. The method of claim 13, further comprising:
switching among the main letter map and a number map, the switching based on at least one of (1) the first value, (2) the second value, or (3) an input signal independent from the first and second values;
the number map including:
the determined input choice is 8 if the first value indicates the passive state and the second value indicates the up direction,
the determined input choice is 9 if the first value indicates the passive state and the second value indicates the right direction,
the determined input choice is 2 if the first value indicates the up direction and the second value indicates the passive state,
the determined input choice is 5 if the first value indicates the up direction and the second value indicates the down direction,
the determined input choice is 0 if the first value indicates the down direction and the second value indicates the passive state,
the determined input choice is 6 if the first value indicates the down direction and the second value indicates the up direction,
the determined input choice is 1 if the first value indicates the left direction and the second value indicates the passive state,
the determined input choice is 4 if the first value indicates the left direction and the second value indicates the left direction,
the determined input choice is 3 if the first value indicates the right direction and the second value indicates the passive state,
the determined input choice is 7 if the first value indicates the right direction and the second value indicates the right direction.
